(19) United States
(12) Patent Application Publication
(10) Pub. No.: US 2025/0284201 A1
(43) Pub. Date: Sep. 11, 2025

(54) Method for forming semiconductor pattern by optical proximity correction

(71) Applicant: UNITED MICROELECTRONICS CORP., Hsin-Chu City (TW)

(72) Inventor: Pin-Han Huang, Tainan City (TW)

(73) Assignee: UNITED MICROELECTRONICS CORP., Hsin-Chu City (TW)

(21) Appl. No.: 18/634,996

(22) Filed: Apr. 14, 2024

(30) Foreign Application Priority Data
Mar. 6, 2024 (TW) 113108109

(51) Int. Cl. G03F 7/00; G03F 1/70

(52) U.S. Cl. CPC G03F 7/70441; G03F 1/70; G03F 7/70625

(57) ABSTRACT

The invention provides a method for forming a semiconductor pattern by optical proximity correction (OPC), which comprises the following steps: inputting a predetermined pattern in a system, performing an optical proximity correction step on the predetermined pattern in the system to correct the predetermined pattern into a correction pattern, and forming the correction pattern on a substrate, wherein the optical proximity correction step comprises: setting a plurality of dissection point on the edge of a weak region of the predetermined pattern, and defining other regions in the predetermined pattern except the weak regions as non-weak regions, and setting a plurality of third dissection points on the edges of the non-weak regions, wherein the density of the dissection points in a fixed unit length is greater than that of the third dissection points in a fixed unit length.

### BACKGROUND OF THE INVENTION

### 1. Field of the Invention

The invention relates to the field of semiconductor manufacturing, in particular to a method for improving optical proximity correction (OPC) quality.

### 2. Description of the Prior Art

In the semiconductor manufacturing process, in order to transfer the pattern of integrated circuits to the semiconductor chip smoothly, it is necessary to design the circuit pattern to form a mask pattern, and then transfer the mask pattern from the mask surface to the semiconductor chip in a certain proportion.

However, as the patterns of integrated circuits are designed to be smaller and smaller, and influenced by the resolution limit of the optical exposure tool, it is easy to produce optical proximity effect (OPE) when these high-density mask patterns are exposed for pattern transfer. For example, right-angled corner rounded, line end shortened and line width increase/decrease are all common mask pattern transfer defects caused by optical proximity effect.

Therefore, in order to avoid the transfer distortion of the mask pattern caused by the above optical proximity effect, and the circuit pattern cannot be transferred to the semiconductor chip correctly, the current semiconductor manufacturing process firstly uses a computer system to perform an optical proximity correction (OPC) on the circuit pattern to eliminate the optical proximity effect, and then makes a mask pattern based on the corrected circuit pattern and forms it on a mask.

Because the conventional optical proximity correction method only uses an optical proximity correction model to correct the whole circuit pattern, it does not consider the exposure deviation caused by uneven pattern density in local regions of the photomask. In addition, with the development of the trend of system on chip (SOC), many different kinds of semiconductor devices (such as memory, logic circuit, input/output, central microprocessor, etc.) are often integrated on the same chip, so as to greatly reduce the cost and improve the processing speed, so the circuit pattern density between different regions on a chip may be quite different, so the conventional optical proximity correction method is not suitable for these devices.

### SUMMARY OF THE INVENTION

The invention provides a method for forming a semiconductor pattern by optical proximity correction (OPC), which comprises the following steps: inputting a predetermined pattern in a system, performing an optical proximity correction step on the predetermined pattern in the system to correct the predetermined pattern into a correction pattern, and forming the correction pattern on a substrate, wherein the optical proximity correction step comprises: setting a plurality of dissection point on the edge of a weak region of the predetermined pattern, and defining other regions in the predetermined pattern except the weak regions as non-weak regions, and setting a plurality of third dissection points on the edges of the non-weak regions, wherein the density of the dissection points in a fixed unit length is greater than that of the third dissection points in a fixed unit length.

To sum up, the present invention provides an improved optical proximity correction method, in which not only the length of each edge is judged as the basis for setting the dissection point, but also the correlation between the pattern and other adjacent or overlapping patterns is considered, so as to find out the weak region. In order to improve the accuracy of optical proximity correction of these weak regions, higher density dissection points will be set in the weak regions. Therefore, the probability of defects in these regions can be greatly reduced. According to the applicant's experimental results, the method of the second embodiment of the present invention is used for optical proximity correction. Compared with the method of the first embodiment, the probability of exposure defects is reduced by about 30-40% when measuring near the first weak region (that is, two similar patterns with small gaps), while the probability of exposure defects is reduced by about 70-90% when measuring near the second weak region (that is, two overlapping patterns with close edges). Therefore, the method provided by the invention can greatly reduce the occurrence probability of exposure defects, and further improve the yield of semiconductor manufacturing process.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

In order to make the following easier to understand, readers can refer to the drawings and their detailed descriptions at the same time when reading the present invention. Through the specific embodiments in the present specification and referring to the corresponding drawings, the specific embodiments of the present invention will be explained in detail, and the working principle of the specific embodiments of the present invention will be expounded. In addition, for the sake of clarity, the features in the drawings may not be drawn to the actual scale, so the dimensions of some features in some drawings may be deliberately enlarged or reduced.

FIG. 1 shows a flowchart of a method for forming a semiconductor pattern by optical proximity correction provided by a first embodiment of the present invention.

FIG. 2 shows an example of a predetermined pattern.

FIG. 3 is a schematic diagram showing that a pattern block is converted into vector data in the system and segmented.

FIG. 4 shows an example diagram after the edge of the pattern of FIG. 2 is segmented according to the method provided in the first embodiment of the present invention.

FIG. 5 shows a flowchart of a method for forming a semiconductor pattern by optical proximity correction provided by the second embodiment of the present invention.

FIG. 6 is a schematic diagram showing that the pattern block is converted into pattern data in the system and finding the first weak region.

FIG. 7 is a schematic diagram showing that the pattern block is converted into pattern data in the system, and finding the second weak region.

FIG. 8 shows an example diagram after the edge of the pattern of FIG. 2 is segmented according to the method provided in the second embodiment of the present invention.

### DETAILED DESCRIPTION

To provide a better understanding of the present invention to users skilled in the technology of the present invention, preferred embodiments are detailed as follows. The preferred embodiments of the present invention are illustrated in the accompanying drawings with numbered elements to clarify the contents and the effects to be achieved.

Please note that the figures are only for illustration and the figures may not be to scale. The scale may be further modified according to different design considerations. When referring to the words “up” or “down” that describe the relationship between components in the text, it is well known in the art and should be clearly understood that these words refer to relative positions that can be inverted to obtain a similar structure, and these structures should therefore not be precluded from the scope of the claims in the present invention.

Although the present invention uses the terms first, second, third, etc. to describe elements, components, regions, layers, and/or sections, it should be understood that such elements, components, regions, layers, and/or sections should not be limited by such terms. These terms are only used to distinguish one element, component, region, layer and/or block from another element, component, region, layer and/or block. They do not imply or represent any previous ordinal number of the element, nor do they represent the arrangement order of one element and another element, or the order of manufacturing methods. Therefore, the first element, component, region, layer or block discussed below can also be referred to as the second element, component, region, layer or block without departing from the specific embodiments of the present invention.

The term “about” or “substantially” mentioned in the present invention usually means within 20% of a given value or range, such as within 10%, or within 5%, or within 3%, or within 2%, or within 1%, or within 0.5%. It should be noted that the quantity provided in the specification is approximate, that is, the meaning of “about” or “substantially” can still be implied without specifying “about” or “substantially”.

The terms “coupling” and “electrical connection” mentioned in the present invention include any direct and indirect means of electrical connection. For example, if the first component is described as being coupled to the second component, it means that the first component can be directly electrically connected to the second component, or indirectly electrically connected to the second component through other devices or connecting means.

Although the invention of the present invention is described below by specific embodiments, the inventive principles of the present invention can also be applied to other embodiments. In addition, in order not to obscure the spirit of the present invention, specific details are omitted, and the omitted details are within the knowledge of those with ordinary knowledge in the technical field.

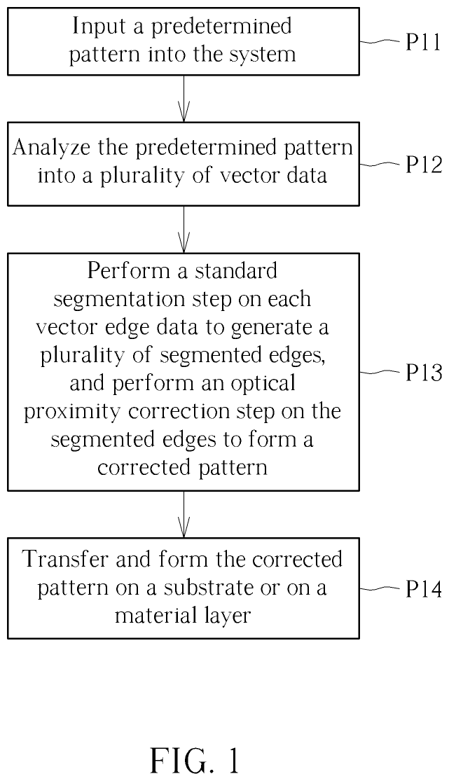

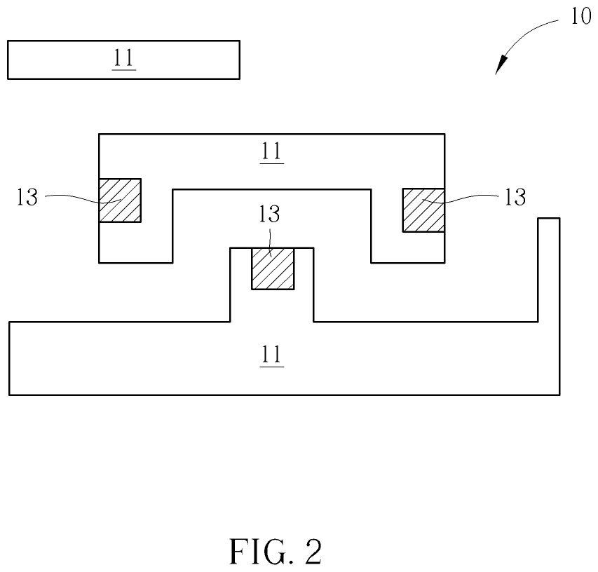

Please refer to FIG. 1 and FIG. 2. FIG. 1 shows a flowchart of a method for forming a semiconductor pattern by optical proximity correction provided by a first embodiment of the present invention, and FIG. 2 shows an example of a predetermined pattern. The first embodiment of the present invention provides a method for forming a semiconductor pattern by optical proximity correction. First, a predetermined pattern 10 as shown in FIG. 2 is input into a system, where the predetermined pattern 10 refers to a pattern transferred to a substrate or a material layer by an exposure and development process in a subsequent semiconductor step, for example, various semiconductor device patterns, such as gates, source/drain, contact structures, conductor patterns, resistors, capacitors and other patterns, are formed in the subsequent step. The pattern shown in FIG. 2 is only one example, and the present invention is not limited to this. In this embodiment, the predetermined pattern 10 includes a plurality of pattern blocks 11 and contact patterns 13, wherein the pattern blocks 11 may correspond to subsequent patterns such as wires, and the contact patterns 13 correspond to subsequent contact vias.

The pattern shown in FIG. 2 is input into the system. The system is, for example, a processor for calculation, such as a computer or a machine tool, which can be used to perform optical proximity correction on the input predetermined pattern 10, regenerate a corrected pattern, and then form the pattern on a substrate or a material layer. As mentioned in the previous paragraph, various optical proximity effects are easy to occur when the pattern transfer step is carried out with the exposure machine, and then pattern defects are generated. Therefore, after the predetermined pattern is corrected by optical proximity correction, the occurrence probability of the above-mentioned various pattern defects can be reduced.

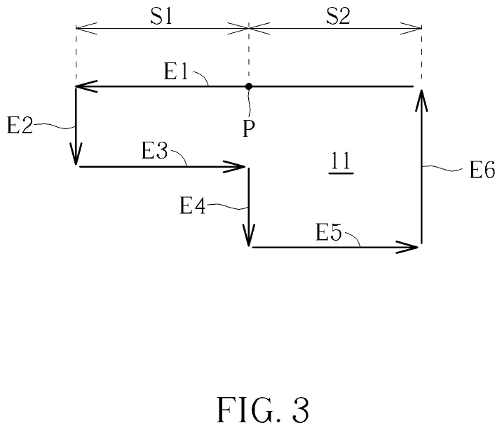

For example, in the first embodiment of the present invention, please refer to step P11: input a predetermined pattern into the system. Next, proceed to step P12: analyze the predetermined pattern into a plurality of vector data. Reference can be made to FIG. 2 and FIG. 3, in which the pattern 10 contains various pattern blocks 11, and these pattern blocks 11 contain their own edges E, and each edge may have different directions and lengths. In the first embodiment of the present invention, each edge E of the pattern block 11 of the predetermined pattern 10 is analyzed into vector data, wherein the vector data contains length and direction values, and the length and direction values are input into the system. As shown in FIG. 3, FIG. 3 shows an example of a pattern block being converted into vector data in the system. In FIG. 3, the edge of an example pattern block 11 is converted into vector data, and the direction and length of the vector are indicated by arrows. The pattern block 11 in FIG. 3 may be one of the predetermined patterns 10, but the shape may change according to the predetermined patterns 10, and the present invention is not limited to this.

In the general optical proximity correction step, after the edges of the pattern block 11 are converted into vector data, each edge is subjected to optical proximity correction to generate edges that can correct optical defects. For example, for the corner region that is prone to rounding, the edge near the corner region can be extended outward to make up for the rounding effect of the pattern in the corner, and make the pattern finally transferred to the material layer as close as possible to the original predetermined pattern. The above description is only one possible optical proximity correction method, and other optical proximity correction techniques are known in the field, so they are not repeated here.

However, in the actual optical proximity correction step, if the length of the edge of the pattern block is longer, it means that the length to be corrected is longer, that is, the range of single correction is larger, which will lead to the worse accuracy of the edge optical proximity correction. On the other hand, if the length of the edge of the pattern block is shorter, the better the accuracy of the optical approximation of the edge after correction. Therefore, in order to avoid the decrease of accuracy caused by the excessively long edge of the pattern block, after the edge of the pattern block 11 is converted into vector data, a segmentation step can be performed to split the excessively long edge into a plurality of shorter line segments, and in the subsequent optical proximity correction, the edges of the split line segments are adjusted respectively.

In more detail, please refer to step P13 in FIG. 3 and FIG. 1 at the same time, P13: perform a standard segmentation step on each vector edge data to generate a plurality of segmented edges, and perform an optical proximity correction step on the segmented edges to form a corrected pattern. As shown in FIG. 3, taking the pattern block 11 as an example, the pattern block 11 includes edges E1, E2, E3, E4, E5 and E6 converted into vector data. Among them, the rules about segmentation can be made by the manufacturer in advance, for example, when the length of the edge is greater than a certain value, the edge is segmented to split the long line segment into a plurality of shorter line segments. For example, in FIG. 3, if the length of the edge E1 is greater than the preset value, a dissection point P is set in the edge E1, and the edge E1 is divided into two line segments S1 and S2 from the dissection point P, while the remaining edges E2, E3, E4, E5 and E6 are not set with dissection points since they are not greater than the preset value, that is, they are not divided into line segments. In the following steps, the line segments S1 and S2 and the edges E2, E3, E4, E5 and E6 will be corrected for optical proximity. In this way, it can be ensured that the accuracy of each edge or line segment for optical proximity correction will not be affected because of its too long length. It is worth noting that the preset values in the above segmentation steps and the length of each line segment after segmentation (that is, the number of dissection points P) can be adjusted according to the needs of manufacturers. The FIG. 3 is only an example, but in other embodiments, it may be changed according to the preset values set in the rules, and other edges (such as edges E2, E3, E4, E5 and E6) may also be segmented.

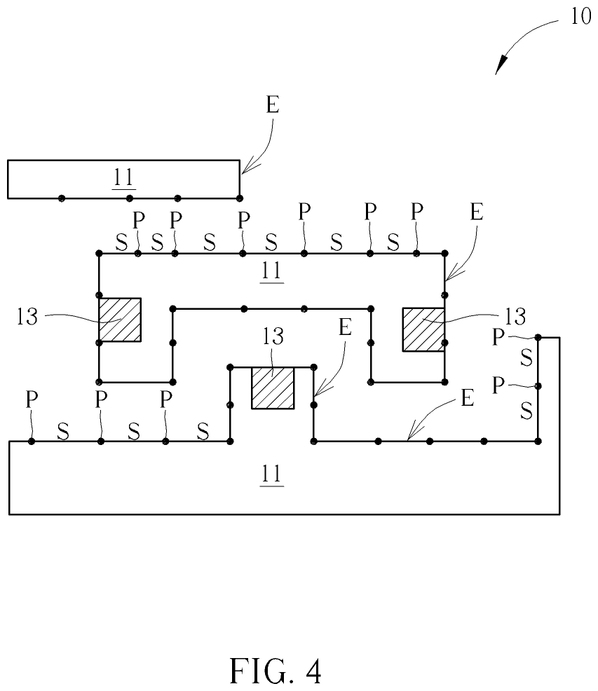

The above-mentioned optical proximity correction step will be carried out in the system, specifically, the edge of each pattern block 11 in the preset pattern 10 will be vectorized, and judging whether there is an edge exceeding the length is determined, and the segmentation step and the edge adjustment step will be carried out. Reference can be made to FIG. 4, which shows an example diagram after the edge of the pattern of FIG. 2 is segmented according to the method provided by the first embodiment of the present invention. Wherein a plurality of line segments are formed after dividing the edges of the preset pattern 10, and each line segment is respectively subjected to optical proximity correction to adjust the edges of the line segments, and after all the line segments are corrected, a corrected pattern is formed.

After the above steps are completed, the preset pattern 10 is corrected into a corrected pattern (i.e., an optical proximity corrected pattern) in the system, that is, an optical proximity corrected pattern is generated. Subsequently, as in step P14 of FIG. 1: transfer and form the corrected pattern on a substrate or on a material layer. After the optical proximity correction, the corrected pattern is transferred to the substrate or material layer, which can reduce the probability of pattern defects.

The applicant found that the first embodiment of the present invention still has spacer for improvement. More specifically, in the first embodiment, each edge E of the pattern block 11 is divided into a plurality of line segments (such as line segments S1 and S2), and the length of each line segment is only affected by two factors, namely the length and the direction of the edge E itself, that is, the two numerical values contained in the vector data. In this way, because the factors considered are not complete enough, pattern defects may still be faced after the actual segmentation step and optical proximity correction.

For example, in the first embodiment of the present invention, a longer edge is cut into a plurality of segments to maintain the accuracy of optical proximity correction. However, in the optical proximity correction, if the same edge is set with more dissection points P, that is, it is divided into more line segments S, which means that the accuracy of this region is higher, but it will also increase the calculation time consumed in performing the optical proximity correction. Therefore, in order to avoid cutting the same edge into too many line segments and affecting the process time, the manufacturer will control the number of dissection points P within an allowable range. At the same time, the manufacturer also considers setting dense dissection points P near the corners of the pattern to maintain the accuracy of the corner region.

Taking FIG. 4 as an example, in order to reduce the rounding problem caused by corner patterns, in the preset pattern 10, the number of dissection points P near the corners of each pattern will increase, that is to say, the length of the line segment S near the corner region is shorter, so the pattern accuracy in the corner region after optical proximity correction is higher, and the pattern transferred to the material layer will be closer to the original preset pattern 10. On the contrary, if it is far away from the edge of the corner region, it is possible to set more scattered dissection points P, in exchange for saving the execution time of optical proximity correction with lower accuracy.

However, according to the optical proximity correction method of the first embodiment of the present invention, only the length and direction of the pattern edge are considered as the factor for setting the dissection point P at each edge, and some practical manufacturing problems cannot be found. For example, during the experiment, the applicant found two problems of optical proximity correction, one of which is that when the distance between one edge E and the other edge is close, it is easy to cause unexpected connection between the patterns of the two edges after exposure due to the difference in pattern density, which may cause short circuit. Another problem is that when the vicinity of the straight line edge E overlaps with the contact pattern, because the accuracy of the edge E in optical proximity correction is low, the pattern in this region may not completely overlap with the contact pattern after exposure, resulting in electrical disconnection and so on. In other words, with the method described in the first embodiment, only the vector data can be used to adjust the edges of the respective edges, but it is still impossible to accurately judge the relationship with other patterns, and it is possible that the above-mentioned adjacent patterns are too close to generate short circuits, or the patterns overlap incompletely with another layer of patterns (such as contact structures). Therefore, the first embodiment of the present invention still has space for improvement.

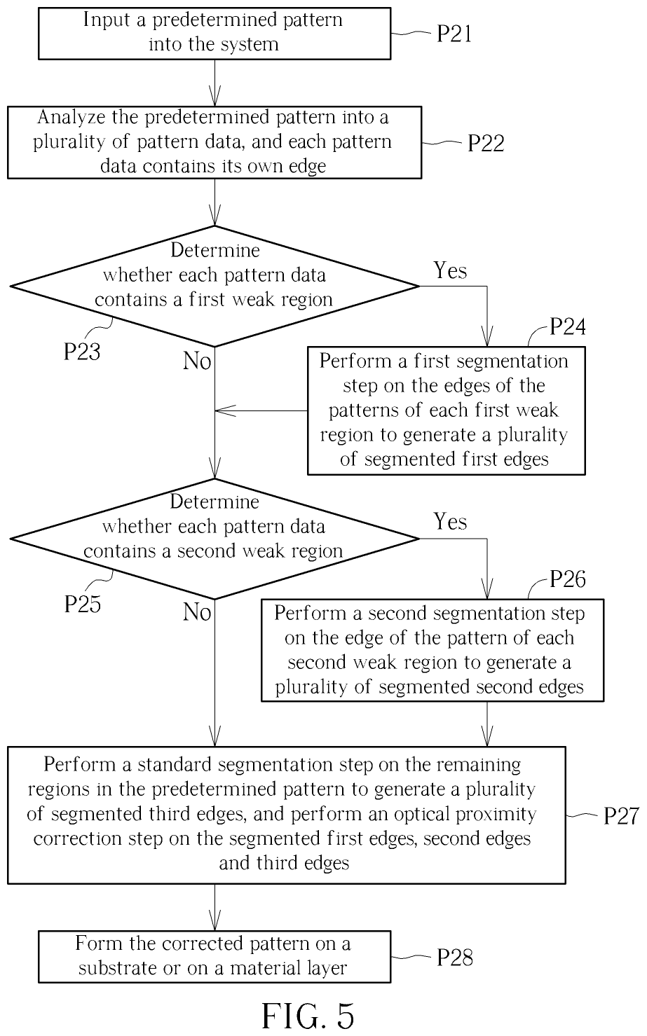

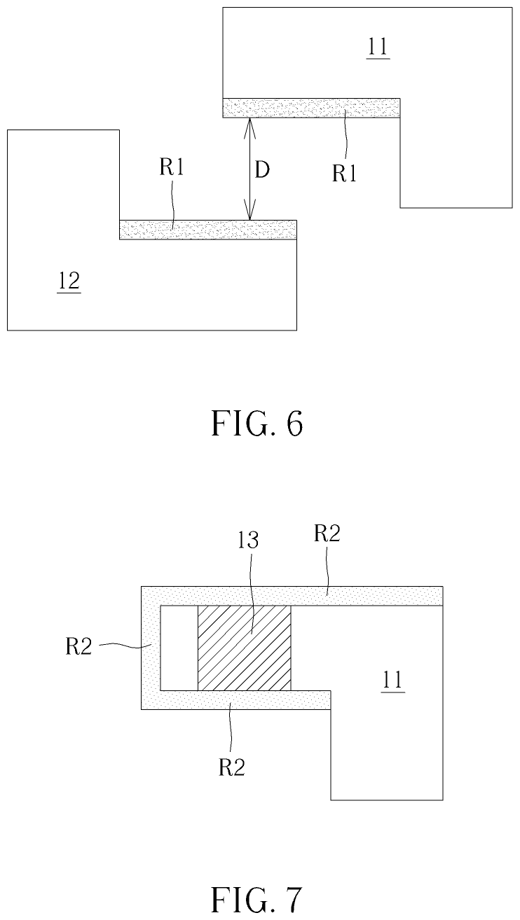

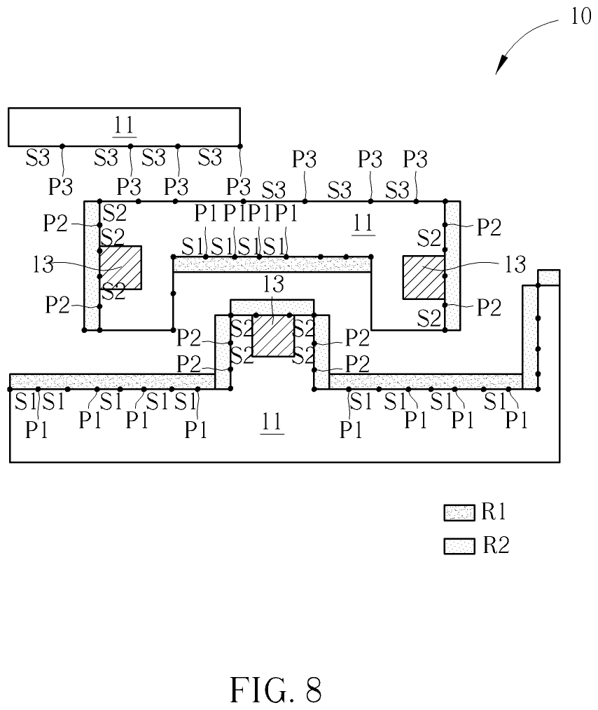

Therefore, the applicant proposes a second embodiment of the present invention on the basis of the above first embodiment. Please refer to FIGS. 5, 6, 7 and 8. FIG. 5 shows a flowchart of a method for forming a semiconductor pattern by optical proximity correction provided by the second embodiment of the present invention, FIG. 6 shows a schematic diagram of converting a pattern block into pattern data and finding out a first weak region in the system, FIG. 7 shows a schematic diagram of converting a pattern block into pattern data and finding out a second weak region in the system, and FIG. 8 shows an example diagram of segmenting the edge of the pattern of FIG. 2 according to the method provided by the second embodiment of the present invention.

First, as shown in FIG. 5, step P21: input a predetermined pattern into the system, which is the same as the above step P11. Next, step P22 is performed: analyze the predetermined pattern into a plurality of pattern data, and each pattern data contains its own edge. The difference between this step and the above step P12 is that after the pattern is input into the system, it is not stored as vector data, but analyzed as polygon data. Therefore, compared with the above-mentioned first embodiment, the analysis method of this embodiment is easier to find the weak region of optical proximity correction, and the weak region here refers to the place where pattern defects are easily generated after optical proximity correction. Details will be explained in the next paragraph.

Next, step P23: determine whether each pattern data contains a first weak region, if yes, step P24: perform a first segmentation step on the edges of the patterns of each first weak region to generate a plurality of segmented first edges, if no, or if the execution of step P24 is completed, step P25: determine whether each pattern data contains a second weak region, if the judgment result is yes, proceed to step P26: perform a second segmentation step on the edge of the pattern of each second weak region to generate a plurality of segmented second edges, if the judgment result of step P25 is no, or the execution of step P26 is completed, proceed to step P27: perform a standard segmentation step on the remaining regions in the predetermined pattern to generate a plurality of segmented third edges, and perform an optical proximity correction step on the segmented first edges, second edges and third edges. Finally, step P28 is performed: form the corrected pattern on a substrate or on a material layer.

Steps P23 and P24 will be described with reference to FIG. 6. FIG. 6 is a schematic diagram showing that the pattern block is converted into pattern data in the system and finding out the first weak region. Because in this embodiment, the predetermined pattern 10 will be preserved and analyzed after being input into the system, unlike the vector data of the first embodiment described above, the pattern data in this embodiment can be further analyzed or found out regions with small gaps between adjacent patterns, which are defined as the first weak regions R1 according to the present invention. As shown in FIG. 6, if the distance between one pattern block 11 and another adjacent pattern block 12 is less than a set distance D, the regions on both sides of this gap will be defined as the first weak region R1. Here, both the pattern block 11 and the pattern block 12 belong to a part of the predetermined pattern 10, and the value of the set distance D can also be determined by the manufacturer. According to the applicant's experiment, the first weak region R1 is a place where exposure defects are easy to occur, for example, two adjacent patterns are easy to connect with each other because of exposure defects, resulting in short circuits. Therefore, the first segmentation step will be performed in the first weak region R1. The first segmentation step mentioned here refers to setting more dissection points P in the first weak region R1 in the subsequent step, so that the first weak region R1 can be corrected for optical proximity more accurately and the probability of pattern defects after exposure and development can be reduced.

Similarly, steps P25 and P26 will be described with reference to FIG. 7. FIG. 7 is a schematic diagram showing that the pattern block is converted into pattern data in the system, and finding the second weak region. In addition to the above-mentioned first weak region R1 (that is, the region where the gap between two adjacent patterns is small), the pattern data in this embodiment can further analyze or find out the regions where defects are easy to occur between different stacked patterns, and these regions are defined as the second weak region R2 according to the present invention. As shown in FIG. 7, one of the edges of a pattern block 11 is close to a contact pattern 13. At this time, the region where the distance between the edge of the pattern block 11 and the contact pattern 13 is less than a set value (which can be defined by the manufacturer) is defined as the second weak region R2. In this embodiment, the second weak region R2 is close to the edge of the contact pattern 13, so there is a possibility that the contact structure 13 cannot be accurately formed on the upper/lower pattern layer (i.e., the pattern block 11 here) due to an error caused by the alignment step in the actual exposure process, resulting in an electrical disconnection. Therefore, the purpose of setting the second weak region R2 in this embodiment is to set more dissection points P for the second weak region R2 to improve the accuracy of optical proximity correction in this region, and in addition, the region of the second weak region R2 can be appropriately expanded in the optical proximity correction step, so that the pattern block 11 can more easily overlap with the contact pattern 13, and the above alignment problem can be avoided.

It is worth noting that the above steps P23 and P24 are steps to find out the first weak region R1 and correct it, while steps P25 and P246 are steps to find out the second weak region R2 and correct it. In the concept of the present invention, the first weak region R1 and the second weak region R2 are regions where exposure defects are more likely to occur, so the density of dissection points P set by them should also be higher than other regions (that is, regions in the predetermined pattern 10 except the first weak region R2 or the second weak region R2).

In addition, it can be understood that the above-mentioned first weak region R1 and second weak region R2 are two kinds of regions that are more prone to exposure defects, and have their own judgment conditional expressions to judge whether a region conforms to the first weak region R1 or the second weak region R2. However, in actual steps, the manufacturer can set other weak regions in the system and define corresponding judgment conditions. For example, in addition to the above-mentioned first weak region R1 and second weak region R2, it may also include other weak regions such as the third weak region and the fourth weak region. Such variations are also within the scope of the present invention.

Next, step P27 is performed: perform a standard segmentation step on the remaining region in the predetermined pattern to generate a plurality of segmented third edges, and perform an optical proximity correction step on the segmented first edges, second edges and third edges to form a corrected pattern. And step P28: form the corrected pattern on a substrate or on a material layer. In more detail, the standard segmentation steps described here are the same as those described in the first embodiment. It is assumed that there are only two conditional expressions for determining the first weak region R1 and the second weak region R2 in the system, that is, the system determines that the risk of exposure defects in other regions except the first weak region R1 and the second weak region R2 is low. At this time, other regions except the first weak region R1 and the second weak region R2 can be set with multiple dissection points P by the above-mentioned standard segmentation steps (same as the segmentation rules of the first embodiment). Referring to FIG. 8 at the same time, after the predetermined pattern 10 finds out the first weak region R1 and the second weak region R2 through the judgment formula, more first dissection points P1 and second dissection points P2 are respectively set in the first weak region R1 and the second weak region R2. In addition, the dissection point P3 will still be set in other regions (the dissection point P3 is the same as the dissection point P in the first embodiment), but the density of the dissection point P3 in other regions is preferably lower than that of the dissection points P1 and P2 included in the first weak region R1 and the second weak region R2. In other words, the first weak region R1 is divided into a plurality of line segments S1 by the first dissection point P1, the second weak region R2 is divided into a plurality of line segments S2 by the second dissection point P2, and other regions are divided into a plurality of line segments S3 by the dissection point P3. Preferably, the lengths of the line segment S1 and the line segment S2 are shorter than the length of the line segment S3.

It is worth noting that in FIG. 8, the line segment between two first dissection points P1 is defined as S1, the line segment between two second dissection points P2 is defined as S2, and the line segment between two dissection points P3 is defined as S3. For the sake of clarity, only some of the first dissection points P1, the second dissection points P2, the dissection points P3, the line segments S1, the line segments S2 and the line segments S3 are drawn, some dissection points and line segments are not labeled in the figure, but it can be judged by its position that it belongs to the first dissection point P1, the second dissection point P2, the dissection point P3 or the line segment S1, the line segment S2 and the line segment S3. In short, the dissection points and line segments located in the first weak region R1 are the first dissection point P1 and the line segment S1, respectively, the dissection points and line segments located in the second weak region R2 are the second dissection point P2 and the line segment S2, and the dissection points and line segments located in other regions are the dissection point P3 and the line segment S3, respectively.

In the following step, the line segments S1, S2 and S3 are respectively subjected to optical proximity correction to adjust the edges of the line segments, and after all the line segments are corrected, a corrected pattern is formed. After the above steps are completed, the predetermined pattern 10 is corrected into a corrected pattern (i.e., an optical proximity corrected pattern) in the system. Subsequently, as shown in step P28 of FIG. 5, the corrected pattern is transferred and formed on a substrate or a material layer. After the optical proximity correction, the corrected pattern is transferred to the substrate or material layer, which can reduce the probability of pattern defects.

Based on the above description and drawings, the present invention provides a method for forming semiconductor patterns by optical proximity correction (OPC), which includes inputting a predetermined pattern 10 in a system, performing an optical proximity correction step on the predetermined pattern in the system to correct the predetermined pattern into a correction pattern, and forming the correction pattern on a substrate. The optical proximity correction step includes: setting a plurality of disconnection points P1/P2 on the edge of a weak region (here, it may refer to the first weak region R1 or the second weak region R2) of the predetermined pattern 10, defining other regions except the weak region in the predetermined pattern 10 as non-weak regions, and setting a plurality of third disconnection points P3 on the edge of the non-weak regions, wherein the density of the disconnection points P1/P2 in a fixed unit length is greater than the third disconnection in a fixed unit length.

In some embodiments of the present invention, the step of setting a plurality of dissection points P1/P2 on the edge of the weak region of the predetermined pattern 10 further comprises determining whether the predetermined pattern 10 contains a first weak region R1, and if the predetermined pattern contains the first weak region R1, setting a plurality of first dissection points P1 on the edge of the first weak region R1, and further determining whether the predetermined pattern 10 contains a second weak region R2, if the predetermined pattern 10 contains the second weak region R2, a plurality of second dissection points P2 are set on the edge of the second weak region R2, and other regions in the predetermined pattern 10 except the first weak region R1 and the second weak region R2 are defined as the non-weak regions, and a plurality of third dissection points P3 are set on the edge of the non-weak regions.

In some embodiments of the present invention, the method for determining whether the predetermined pattern 10 contains the first weak region R1 includes: performing a judgment formula A: whether the predetermined pattern 10 contains two adjacent patterns (for example, the pattern block 11 and the pattern block 12 in FIG. 6) and the gap between them is less than a preset value, and if the result of the judgment formula A is yes, setting the adjacent regions of the two adjacent patterns as the first weak region R1 (refer to the FIGS. 5 and 6 together).

In some embodiments of the present invention, if the result of formula A is negative, the predetermined pattern 10 does not include the first weak region R1 (refer to FIG. 5 together).

In some embodiments of the present invention, the method for determining whether the predetermined pattern 10 contains the second weak region R2 comprises: performing a judgment formula B: determining whether the predetermined pattern 10 contains two mutually stacked patterns (such as the pattern block 11 and the contact pattern 13 in FIG. 7), and if so, defining the two patterns as a lower layer pattern and an upper layer pattern respectively, and performing a judgment formula C: judging whether the distance between the edge of the lower layer pattern and the edge of the upper layer pattern is less than a preset value, and if the result of the judgment formula C is yes, setting the region near the stacking of the lower layer pattern and the upper layer pattern as a second weak region R2. In other words, as shown in FIG. 7, if the edge distance between the pattern block 11 and the contact pattern 13 is less than a preset value, the vicinity of this region is defined as the second weak region R2.

In some embodiments of the present invention, if the result of the aforementioned judgment formula C is negative, the predetermined pattern 10 does not include the second weak region R2.

In some embodiments of the present invention, in the subsequent step, the lower pattern corresponds to a metal layer on the substrate, and the upper pattern corresponds to a contact pattern on the substrate.

In some embodiments of the present invention, a plurality of first dissection points P1 are arranged on the edge of the first weak region R1, and in a fixed unit length, one edge of the first weak region R1 contains X first line segments S1.

In some embodiments of the present invention, a plurality of second dissection points P2 are arranged on the edge of the second weak region R2, and in a fixed unit length, one edge of the second weak region R2 contains Y second line segments S2.

In some embodiments of the present invention, a plurality of third dissection points P3 are arranged on the edge of the non-weak region, and in a fixed unit length, the edge of the non-weak region contains Z third line segments S3, where both X and Y are greater than Z.

In some embodiments of the present invention, after setting a plurality of first dissection points P1, a plurality of second dissection points P2 and a plurality of third dissection points P3 in each region of the predetermined pattern 10, an edge correction step (i.e., the optical proximity correction step) is performed on the edges of each region.

In some embodiments of the present invention, after the edge correction step (the optical proximity correction step), the correction pattern is completed and directly formed on the substrate. In other words, it is preferable that the correction pattern is formed on the substrate or the material layer after the optical proximity correction step is performed only once, and another optical proximity correction step is not repeated.

To sum up, the present invention provides an improved optical proximity correction method, in which not only the length of each edge is judged as the basis for setting the dissection point, but also the correlation between the pattern and other adjacent or overlapping patterns is considered, so as to find out the weak region. In order to improve the accuracy of optical proximity correction of these weak regions, higher density dissection points will be set in the weak regions. Therefore, the probability of defects in these regions can be greatly reduced. According to the applicant's experimental results, the method of the second embodiment of the present invention is used for optical proximity correction. Compared with the method of the first embodiment, the probability of exposure defects is reduced by about 30-40% when measuring near the first weak region (that is, two similar patterns with small gaps), while the probability of exposure defects is reduced by about 70-90% when measuring near the second weak region (that is, two overlapping patterns with close edges). Therefore, the method provided by the invention can greatly reduce the occurrence probability of exposure defects, and further improve the yield of semiconductor manufacturing process.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A method of forming a semiconductor pattern by optical proximity correction, comprising:
inputting a predetermined pattern in a system, performing an optical proximity correction step on the predetermined pattern in the system to correct the predetermined pattern into a correction pattern, and forming the correction pattern on a substrate, wherein the optical proximity correction step comprises:
setting a plurality of first dissection points on the edge of a first weak region of the predetermined pattern;
defining a non-weak region in the predetermined pattern, and a plurality of third dissection points are arranged on the edge of the non-weak region, wherein the density of the first dissection points in a fixed unit length is greater than that of the third dissection points in the fixed unit length.

2. The method for forming a semiconductor pattern by optical proximity correction according to claim 1, further comprising:
judging whether the predetermined pattern contains the first weak region;
if the predetermined pattern contains the first weak region, a plurality of first dissection points are arranged on the edge of the first weak region;
judging whether the predetermined pattern contains a second weak region;
if the predetermined pattern contains the second weak region, a plurality of second dissection points are arranged on the edge of the second weak region;
defining other regions in the predetermined pattern except the first weak region and the second weak region as the non-weak region, and setting a plurality of third dissection points on the edge of the non-weak region.

3. The method for forming a semiconductor pattern by optical proximity correction according to claim 2, wherein the method for determining whether the predetermined pattern contains the first weak region comprises:
performing a judgment formula A: judging whether the gap between two adjacent patterns is less than a preset value in the predetermined pattern;
if the result of the judgment formula A is yes, the region near the two adjacent patterns is set as the first weak region.

4. The method for forming a semiconductor pattern by optical proximity correction according to claim 3, wherein if the result of the judgment formula A is negative, the predetermined pattern does not include the first weak region.

5. The method for forming a semiconductor pattern by optical proximity correction according to claim 2, wherein the method for determining whether the predetermined pattern contains the second weak region comprises:
performing a judgment formula B: judging whether the predetermined pattern contains two mutually stacked patterns, and if so, respectively defining the two patterns as a lower layer pattern and an upper layer pattern; and
performing a judgment formula C: judging whether the distance between an edge of the lower layer pattern and an edge of the upper layer pattern is less than a preset value;
if the result of the judgment formula C is yes, the region near the stack of the lower layer pattern and the upper layer pattern is set as the second weak region.

6. The method for forming a semiconductor pattern by optical proximity correction according to claim 5, wherein if the result of the above judgment formula C is negative, the predetermined pattern does not include the second weak region.

7. The method for forming a semiconductor pattern by optical proximity correction according to claim 5, wherein in the subsequent step, the lower pattern corresponds to a metal layer on the substrate, and the upper pattern corresponds to a contact pattern on the substrate.

8. The method for forming a semiconductor pattern by optical proximity correction according to claim 2, wherein the plurality of first dissection points are arranged on the edge of the first weak region, and in the fixed unit length, one edge of the first weak region contains X first line segments.

9. The method for forming a semiconductor pattern by optical proximity correction according to claim 8, wherein the plurality of second dissection points are arranged on the edge of the second weak region, and in the fixed unit length, one edge of the second weak region contains Y second line segments.

10. The method for forming a semiconductor pattern by optical proximity correction according to claim 9, wherein the plurality of third dissection points are arranged on the edge of the non-weak region, and in the fixed unit length, the edge of the non-weak region contains Z third line segments, wherein both X and Y are greater than Z.

11. The method for forming a semiconductor pattern by optical proximity correction according to claim 2, wherein after setting a plurality of first dissection points, a plurality of second dissection points and a plurality of third dissection points in each region of the predetermined pattern, the optical proximity correction step is performed on the edges of each region.

12. The method for forming a semiconductor pattern by optical proximity correction according to claim 11, after the optical proximity correction step, the correction pattern is completed and directly formed on the substrate.
